(19) United States
(12) Patent Application Publication
(10) Pub. No.: US 2003/0049570 A1
(43) Pub. Date: Mar. 13, 2003

(54) Pattern formation method

(75) Inventors: Masayuki Endo, Osaka (JP); Masaru Sasago, Osaka (JP)

Correspondence Address: NIXON PEABODY, LLP, 8180 GREENSBORO DRIVE, SUITE 800, MCLEAN, VA, 22102, US

(73) Assignee: MATSUSHITA ELECTRIC INDUSTRIAL CO., LTD., Osaka (JP)

(21) Appl. No.: 10/236,921

(22) Filed: Sep. 9, 2002

(30) Foreign Application Priority Data
Sep. 13, 2001 (JP) 2001-277992

(51) Int. Cl. G03F 7/30; G03F 7/42

(52) U.S. Cl. 430/329; 430/313; 430/331

(57) ABSTRACT

In the pattern formation method of the invention, a resist film made of a chemically amplified resist is formed on a substrate. The resist film is selectively exposed to light for pattern exposure. The pattern-exposed resist film is subjected to a developer, and the resultant resist film is rinsed with an alkaline rinsing liquid to form a resist pattern made of the resist film.

### BACKGROUND OF THE INVENTION

The present invention relates to a method for forming a resist pattern of a chemically amplified resist used in a fabrication process for semiconductor integrated circuit devices.

In fabrication of semiconductor integrated circuit devices, with demands for higher integration of semiconductor integrated circuits and finer semiconductor elements, ever finer patterns have been requested for resist patterns formed by lithography.

To attain finer resist patterns, a chemically amplified resist material having high resolution and high sensitivity is preferably used for formation of resist patterns.

With the demand for finer resist patterns, also, the aspect ratio of the resist patterns must be higher.

A conventional pattern formation method for forming a resist pattern having a high aspect ratio made of a chemically amplified resist material will be described with reference to FIGS. 9A to 9C and 10A to 10C.

As shown in FIG. 9A, a commercially available chemically amplified resist material (PAR-101 from Sumitomo Chemical Co., Ltd.) is applied to a semiconductor substrate 1, to form a resist film 2 having a thickness of 0.4 μm.

As shown in FIG. 9B, the resist film 2 is exposed to ArF excimer laser light (wavelength: 193 nm band) through a photomask 3 having a desired mask pattern under the condition of a numerical aperture NA of 0.60, to perform pattern exposure.

As shown in FIG. 9C, the pattern-exposed resist film 2 is heated with a hot plate at 105° C. for 90 seconds (post exposure bake (PEB)). By this heating, exposed portions 2a of the resist film 2 become soluble in an alkaline developer due to action of acid generating from an acid generator. On the contrary, non-exposed portions 2b of the resist film 2 remain insoluble in an alkaline developer because no acid is generated from the acid generator.

As shown in FIG. 10A, the resist film 2 is developed by being subjected to an alkaline developer 5 made of a 2.38 wt % tetramethylammonium hydroxide solution, for example, for 60 seconds. Thereafter, as shown in FIG. 10B, the developed resist film 2 is rinsed with a rinsing liquid 7 of pure water for 60 seconds, to form a resist pattern 6 composed of the non-exposed portions 2b of the resist film 2 having a line width of 0.11 μm.

However, a problem arises during rinsing of the resist pattern 6 with the rinsing liquid 7. That is, as shown in FIG. 10C, pattern portions of the resist pattern 6 having a high aspect ratio tend to tilt/fall due to the surface tension of the rinsing liquid 7.

When such a resist pattern 6 with tilting/falling pattern portions is used as a mask, the shape of the resultant pattern is inferior. This reduces the yield of the resultant semiconductor devices.

### SUMMARY OF THE INVENTION

An object of the present invention is providing a pattern formation method capable of providing a resist pattern having a high aspect ratio kept in a good shape without tilting/falling of pattern portions.

The first pattern formation method of the present invention includes the steps of: forming a resist film made of a chemically amplified resist on a substrate; exposing the resist film to light selectively to perform pattern exposure; subjecting the pattern-exposed resist film to a developer; and rinsing the resist film subjected to the developer to form a resist pattern made of the resist film, wherein the step of rinsing is performed using an alkaline rinsing liquid.

According to the first pattern formation method, the developed resist film is rinsed with an alkaline rinsing liquid having a surface tension lower than that of pure water. This reduces the surface tension the resist pattern receives from the rinsing liquid, and thus the resist pattern can be kept in a good shape without tilting/falling of pattern portions.

The second pattern formation method of the present invention includes the steps of: forming a resist film made of a chemically amplified resist on a substrate; exposing the resist film to light selectively to perform pattern exposure; subjecting the pattern-exposed resist film to a developer; and rinsing the resist film subjected to the developer to form a resist pattern made of the resist film, wherein the step of rinsing is performed using a rinsing liquid containing an organic solvent.

According to the second pattern formation method, the developed resist film is rinsed with an alkaline rinsing liquid containing an organic solvent having a surface tension lower than that of pure water. This reduces the surface tension the resist pattern receives from the rinsing liquid, and thus the resist pattern can be kept in a good shape without tilting/falling of pattern portions.

The third pattern formation method of the present invention includes the steps of: forming a resist film made of a chemically amplified resist on a substrate; exposing the resist film to light selectively to perform pattern exposure; subjecting the pattern-exposed resist film to a developer; and rinsing the resist film subjected to the developer to form a resist pattern made of the resist film, wherein the step of rinsing is performed using an alkaline rinsing liquid containing an organic solvent.

According to the third pattern formation method, the developed resist film is rinsed with an alkaline rinsing liquid containing an organic solvent having a surface tension lower than that of pure water. This reduces the surface tension the resist pattern receives from the rinsing liquid, and thus the resist pattern can be kept in a good shape without tilting/falling of pattern portions. In addition, by using an alkaline rinsing liquid containing an organic solvent, it is possible to suppress both an adverse effect of an alkaline substance on the resist pattern and an adverse effect of an organic solvent on the environment.

The fourth pattern formation method of the present invention includes the steps of: forming a resist film made of a chemically amplified resist on a substrate; exposing the resist film to light selectively to perform pattern exposure; subjecting the pattern-exposed resist film to a developer; and rinsing the resist film subjected to the developer to form a resist pattern made of the resist film, wherein the step of rinsing includes the step of supplying a rinsing liquid to the resist film while shaking the resist film.

According to the fourth pattern formation method, the surface tension of the rinsing liquid acts on the resist pattern in different directions. Therefore, a lower surface tension is received by the resist pattern compared with the case that the surface tension acts on the resist pattern in a constant direction. Thus, the resist pattern can be kept in a good shape without tilting/falling of pattern portions.

The fifth pattern formation method of the present invention includes the steps of: forming a resist film made of a chemically amplified resist on a substrate; exposing the resist film to light selectively to perform pattern exposure; subjecting the pattern-exposed resist film to a developer; and rinsing the resist film subjected to the developer to form a resist pattern made of the resist film, wherein the step of rinsing comprises the step of spraying an atomized rinsing liquid on the resist film.

According to the fifth pattern formation method, an atomized rinsing liquid is sprayed on the resist film. Therefore, the rinsing liquid less easily stays in openings of the resist pattern compared with the case of supplying a rinsing liquid from a nozzle. This reduces the surface tension acting on the resist pattern, and thus the resist pattern can be kept in a good shape without tilting/falling of pattern portions.

In the fourth or fifth pattern formation method, the rinsing liquid is preferably an alkaline rinsing liquid or an alkaline rinsing liquid containing an organic solvent.

The surface tension of such a rising liquid itself is low, and thus the surface tension acting on the resist pattern can be greatly reduced.

In the first, third, fourth or fifth pattern formation method, when the rinsing liquid is an alkaline rinsing liquid or an alkaline rinsing liquid containing an organic solvent, the alkaline rinsing liquid is preferably a diluted alkaline developer.

In the fourth or fifth pattern formation method, the rising liquid is preferably a rinsing liquid containing an organic solvent or an alkaline rising liquid containing an organic solvent.

In the second, third, fourth or fifth pattern formation method, when the rising liquid is a rinsing liquid containing an organic solvent or an alkaline rising liquid containing an organic solvent, the organic solvent is preferably selected from the group consisting of acetone, methanol, ethanol, isopropyl alcohol, ethyl lactate, propylene glycol methyl ether acetate, propylene glycol methyl ether and diglyme.

### BRIEF DESCRIPTION OF THE DRAWINGS

FIGS. 1A to 1C are cross-sectional views showing steps of a pattern formation method of Embodiment 1 of the present invention.

FIGS. 2A to 2C are cross-sectional views showing subsequent steps of the pattern formation method of Embodiment 1 of the present invention.

FIGS. 3A to 3C are cross-sectional views showing steps of a pattern formation method of Embodiment 2 of the present invention.

FIGS. 4A to 4C are cross-sectional views showing subsequent steps of the pattern formation method of Embodiment 2 of the present invention.

FIGS. 5A to 5C are cross-sectional views showing steps of a pattern formation method of Embodiment 3 of the present invention.

FIGS. 6A to 6C are cross-sectional views showing subsequent steps of the pattern formation method of Embodiment 3 of the present invention.

FIGS. 7A to 7C are cross-sectional views showing steps of a pattern formation method of Embodiment 4 of the present invention.

FIGS. 8A to 8C are cross-sectional views showing subsequent steps of the pattern formation method of Embodiment 4 of the present invention.

FIGS. 9A to 9C are cross-sectional views showing steps of a conventional pattern formation method.

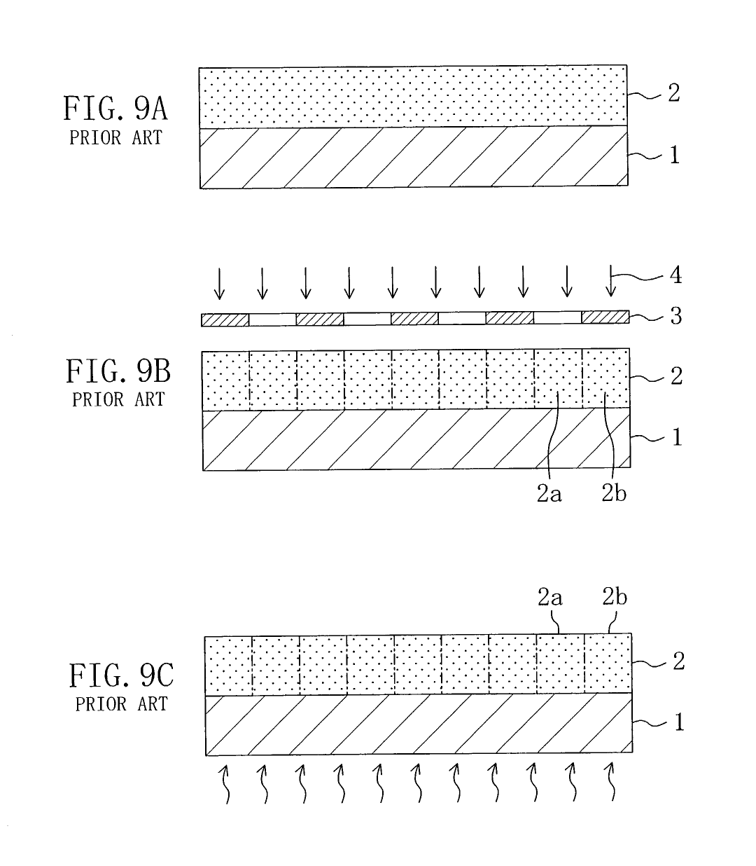

FIGS. 10A to 10C are cross-sectional views showing subsequent steps of the conventional pattern formation method.

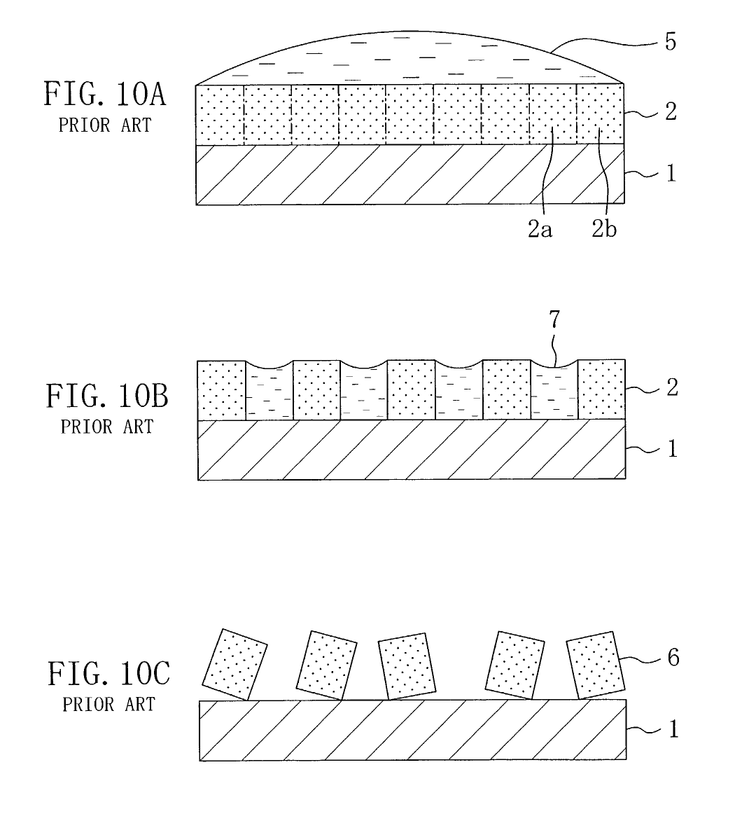

### DESCRIPTION OF THE PREFERRED EMBODIMENTS

Embodiment 1

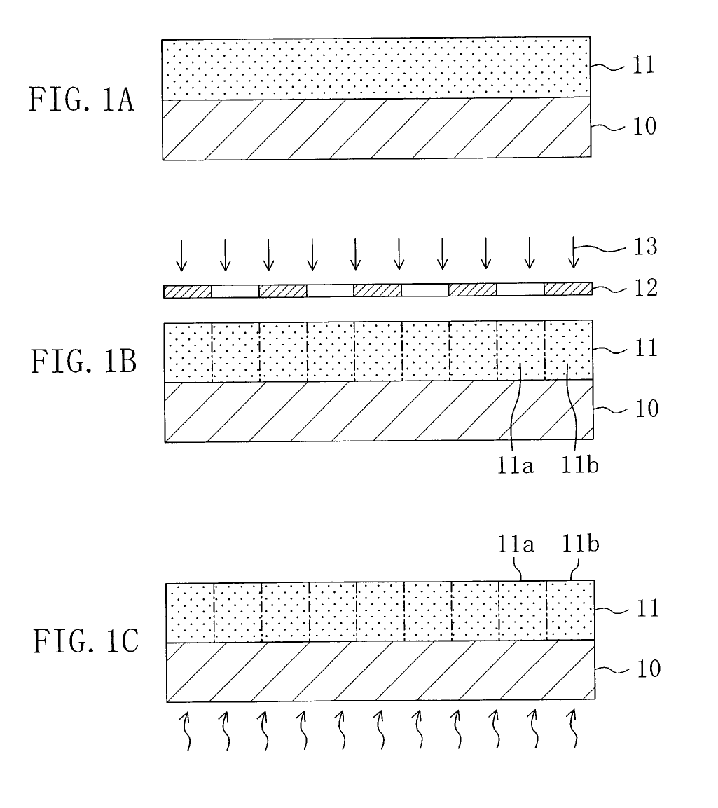

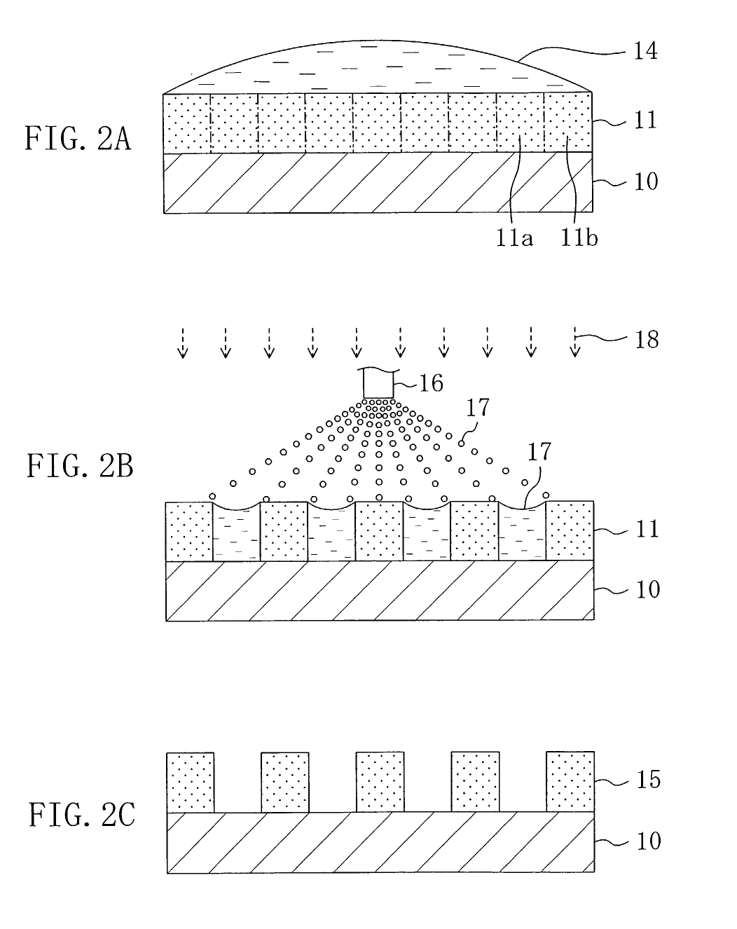

A pattern formation method of Embodiment 1 of the present invention will be described with reference to FIGS. 1A to 1C and 2A to 2C.

As shown in FIG. 1A, a commercially available chemically amplified resist material (PAR-101 from Sumitomo Chemical Co., Ltd.) is applied to a semiconductor substrate 10, to form a resist film 11 having a thickness of 0.4 μm.

As shown in FIG. 1B, the resist film 11 is exposed to ArF excimer laser light (wavelength: 193 nm band) through a mask 12 having a desired mask pattern under the exposure condition of a numerical aperture NA of 0.60, to perform pattern exposure.

As shown in FIG. 1C, the pattern-exposed resist film 11 is heated with a hot plate at 105° C. for 90 seconds (PEB). By this heating, exposed portions 11a of the resist film 11 become soluble in an alkaline developer because a protecting group of a base polymer is eliminated due to action of acid generating from an acid generator. On the contrary, non-exposed portions 11b of the resist film 11 remain insoluble in an alkaline developer because the protecting group of the base polymer is not eliminated due to lack of generation of acid from the acid generator.

As shown in FIG. 2A, the resist film 11 is developed by being subjected to an alkaline developer 14 made of a 2.38 wt % tetramethylammonium hydroxide solution, for example, for 60 seconds.

As shown in FIG. 2B, the developed resist film 11 is rinsed with an alkaline rinsing liquid (a dilution of the alkaline developer) 17 of 0.1 wt % tetramethylammonium hydroxide in pure water, which is supplied from a nozzle 16 for 60 seconds, to thereby form a resist pattern 15 composed of the non-exposed portions 11b of the resist film 11 having a line width of 0.11 μm, as shown in FIG. 2C.

In Embodiment 1, the developed resist film 11 is rinsed with an alkaline rinsing liquid having a surface tension lower than that of pure water. Therefore, the resist pattern 15 receives a reduced surface tension from the rinsing liquid and thus can be kept in good shape without tilting/falling of pattern portions.

The alkaline rinsing liquid 17 used in Embodiment 1 may otherwise be an alkaline solution of 0.2 wt % tetraethylammonium hydroxide in pure water, an alkaline solution of 0.07 wt % trimethylammonium hydroxide in pure water, an alkaline solution of 0.5 wt % tetra-n-propylammonium hydroxide in pure water, or an alkaline solution of 0.1 wt % choline in pure water.

As described above, the alkali content of the alkaline rinsing liquid is preferably set in the range of 0.01 wt % to 1 wt %. With the alkali content of 0.01 wt % or more, it is ensured that the surface tension of the alkaline rinsing liquid is lower than that of pure water. Therefore, pattern portions of the resist pattern 15 are prevented from tilting/falling. Also, with the alkali content of 1 wt% or less, the resist pattern 15 is prevented from being dissolved in the alkaline rinsing liquid.

Embodiment 2

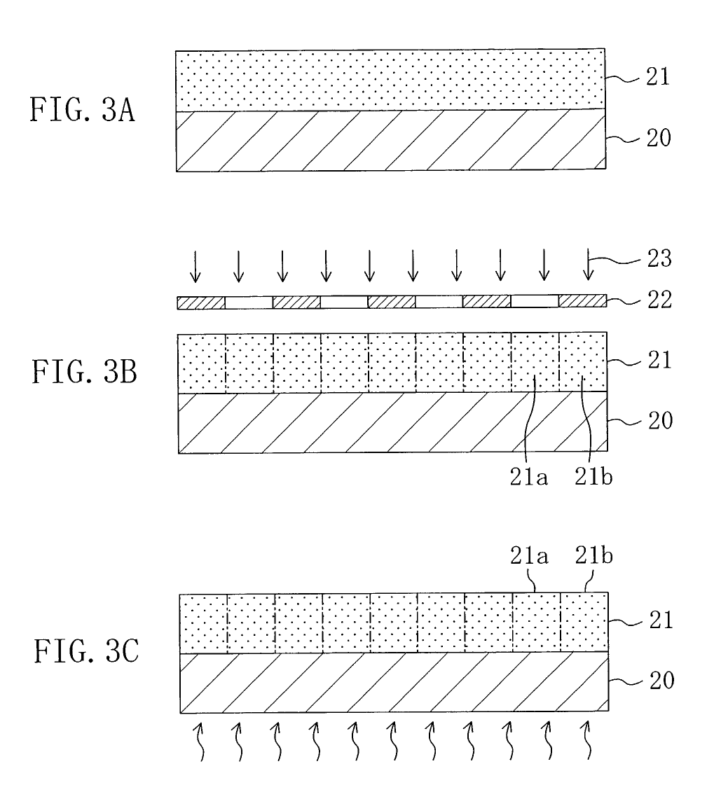

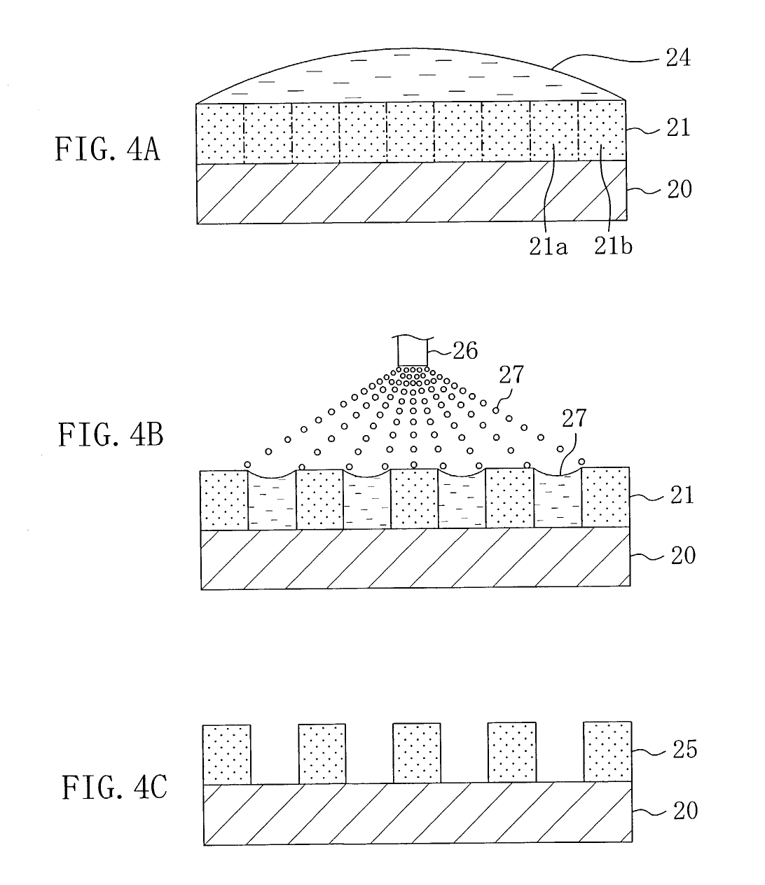

A pattern formation method of Embodiment 2 of the present invention will be described with reference to FIGS. 3A to 3C and 4A to 4C.

As shown in FIG. 3A, a commercially available chemically amplified resist material (PAR-101 from Sumitomo Chemical Co., Ltd.) is applied to a semiconductor substrate 20, to form a resist film 21 having a thickness of 0.4 μm.

As shown in FIG. 3B, the resist film 21 is exposed to ArF excimer laser light (wavelength: 193 nm band) through a mask 22 having a desired mask pattern under the exposure condition of a numerical aperture NA of 0.60, to perform pattern exposure.

As shown in FIG. 3C, the pattern-exposed resist film 21 is heated with a hot plate at 105° C. for 90 seconds (PEB). By this heating, exposed portions 21a of the resist film 21 become soluble in an alkaline developer because a protecting group of a base polymer is eliminated due to action of acid generating from an acid generator. On the contrary, non-exposed portions 21b of the resist film 21 remain insoluble in an alkaline developer because the protecting group of the base polymer is not eliminated due to lack of generation of acid from the acid generator.

As shown in FIG. 4A, the resist film 21 is developed by being subjected to an alkaline developer 24 made of a 2.38 wt % tetramethylammonium hydroxide solution, for example, for 60 seconds.

As shown in FIG. 4B, the developed resist film 21 is rinsed with a rinsing liquid 27 containing an organic solvent, such as a rinsing liquid of 0.3 wt % propylene glycol methyl ether acetate in pure water, supplied from a nozzle 26 for 60 seconds, to thereby form a resist pattern 25 composed of the non-exposed portions 21b of the resist film 21 having a line width of 0.11 μm, as shown in FIG. 4C.

In Embodiment 2, the developed resist film 21 is rinsed with the organic solvent-containing rinsing liquid 27 having a surface tension lower than that of pure water. Therefore, the resist pattern 25 receives a reduced surface tension from the rinsing liquid and thus can be kept in a good shape without tilting/falling of pattern portions.

In the above example, propylene glycol methyl ether acetate was used as the organic solvent of the rinsing liquid 27. Alternatively, acetone, methanol, ethanol, isopropyl alcohol, ethyl lactate, propylene glycol methyl ether, diglyme or the like may be used. The content of such an organic solvent is preferably set in the range of 0.01 wt % to 1 wt %. Having this level of content of an organic solvent, the surface tension of the rinsing liquid can be reduced without adversely affecting the environment.

In Embodiment 2, the rinsing liquid containing an organic solvent in pure water was used. Alternatively, an organic solvent-containing alkaline rinsing liquid, containing 0.1 wt % triethanolamine (alkali) and 0.5 wt % isopropyl alcohol (organic solvent) in pure water may be used.

Using the rinsing liquid described above, the surface tension of the rinsing liquid can be reduced while suppressing an adverse effect on the resist pattern 25 and an adverse effect on the environment.

Embodiment 3

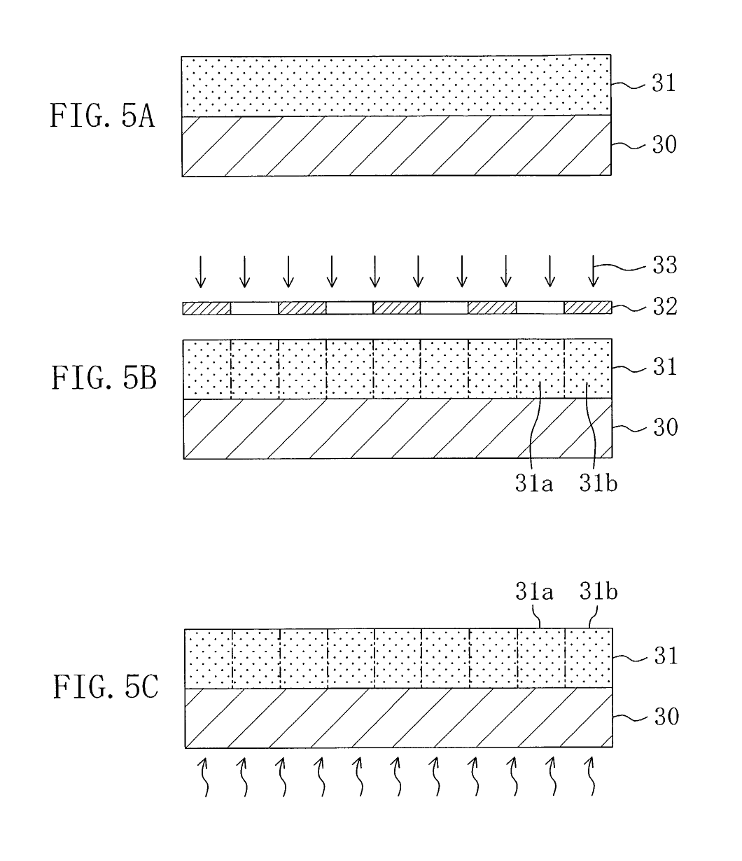

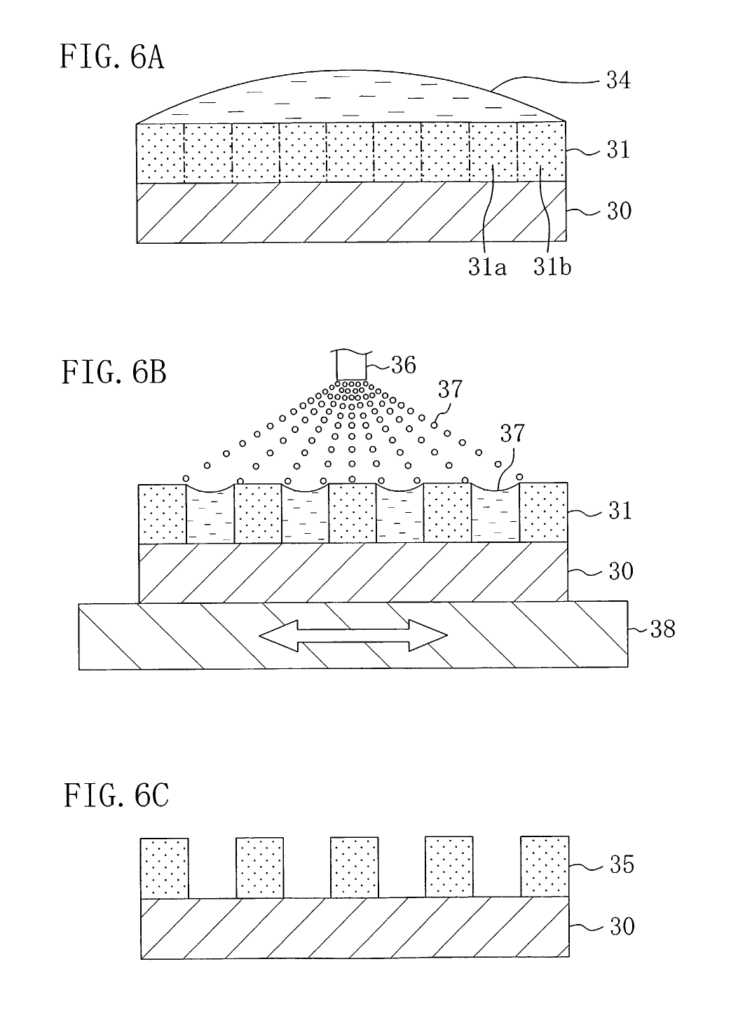

A pattern formation method of Embodiment 3 of the present invention will be described with reference to FIGS. 5A to 5C and 6A to 6C.

As shown in FIG. 5A, a commercially available chemically amplified resist material (PAR-101 from Sumitomo Chemical Co., Ltd.) is applied to a semiconductor substrate 30, to form a resist film 31 having a thickness of 0.4 μm.

As shown in FIG. 5B, the resist film 31 is exposed to ArF excimer laser light (wavelength: 193 nm band) through a mask 32 having a desired mask pattern under the exposure condition of a numerical aperture NA of 0.60, to perform pattern exposure.

As shown in FIG. 5C, the pattern-exposed resist film 31 is heated with a hot plate at 105° C. for 90 seconds (PEB). By this heating, exposed portions 31a of the resist film 31 become soluble in an alkaline developer because a protecting group of a base polymer is eliminated due to action of acid generating from an acid generator. On the contrary, non-exposed portions 31b of the resist film 31 remain insoluble in an alkaline developer because the protecting group of the base polymer is not eliminated due to lack of generation of acid from the acid generator.

As shown in FIG. 6A, the resist film 31 is developed by being subjected to an alkaline developer 34 of a 2.38 wt % tetramethylammonium hydroxide solution, for example, for 60 seconds.

As shown in FIG. 6B, the developed resist film 31 is rinsed with a rinsing liquid 37 of pure water supplied from a nozzle 36 for 60 seconds while a sample stage 38 holding the semiconductor substrate 30 is shaken, to thereby form a resist pattern 35 composed of the non-exposed portions 31b of the resist film 31 having a line width of 0.11 μm, as shown in FIG. 6C.

In Embodiment 3, the developed resist film 31 is rinsed with the rinsing liquid 37 while being shaken. Therefore, the surface tension of the rinsing liquid 37 acts on the resist pattern 35 in different directions. As a result, a lower surface tension is received by the resist pattern 35 compared with the case that the surface tension acts on the resist pattern 35 in a constant direction. Thus, the resist pattern 25 can be kept in a good shape without tilting/falling of pattern portions.

The developed resist film 31 may be shaken in linear directions or rotational directions, preferably by a distance of each shake of about 5 cm at a cycle of one shake per second. In other words, the resist film 31 is preferably shaken at a rate of about 10 cm per second.

In Embodiment 3, pure water was used as the rinsing liquid 37. Alternatively, the rinsing liquid 37 may be the alkaline rinsing liquid shown in Embodiment 1, or the organic solvent-containing rinsing liquid or the organic solvent-containing alkaline rinsing liquid shown in Embodiment 2.

Embodiment 4

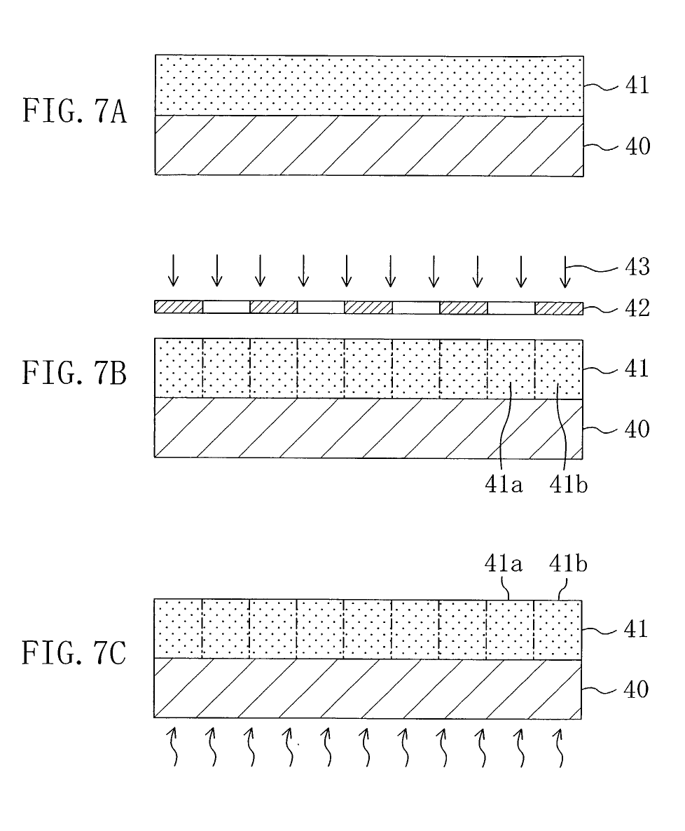

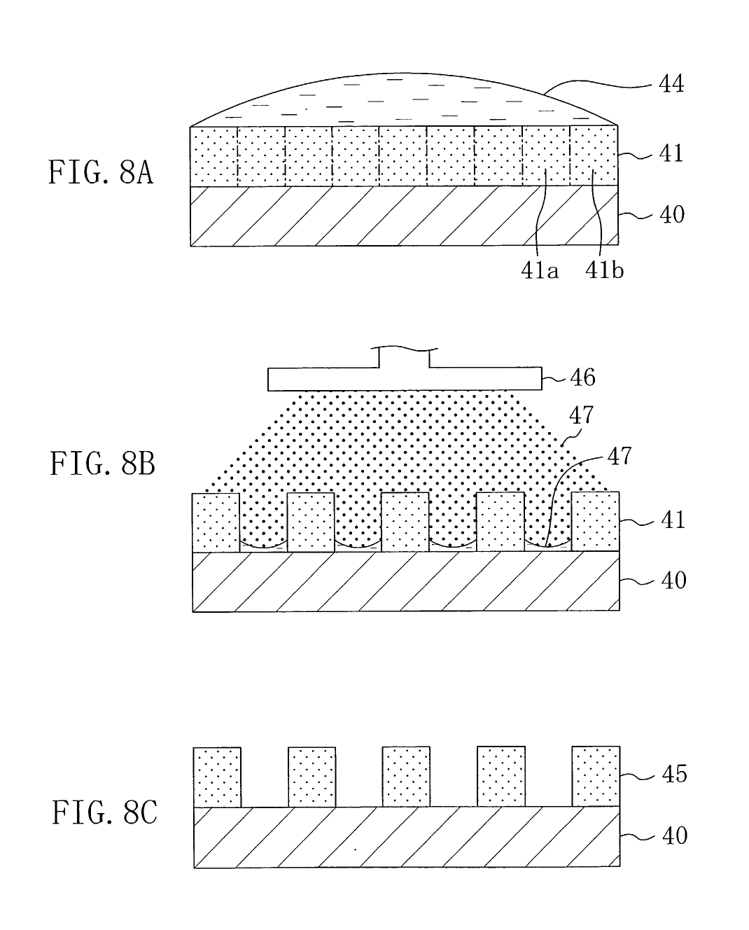

A pattern formation method of Embodiment 4 of the present invention will be described with reference to FIGS. 7A to 7C and 8A to 8C.

As shown in FIG. 7A, a commercially available chemically amplified resist material (PAR-101 from Sumitomo Chemical Co., Ltd.) is applied to a semiconductor substrate 40, to form a resist film 41 having a thickness of 0.4 μm.

As shown in FIG. 7B, the resist film 41 is exposed to ArF excimer laser light (wavelength: 193 nm band) through a mask 42 having a desired mask pattern under the exposure condition of a numerical aperture NA of 0.60, to perform pattern exposure.

As shown in FIG. 7C, the pattern-exposed resist film 41 is heated with a hot plate at 105° C. for 90 seconds (PEB). By this heating, exposed portions 41a of the resist film 41 become soluble in an alkaline developer because a protecting group of a base polymer is eliminated due to action of acid generating from an acid generator. On the contrary, non-exposed portions 41b of the resist film 41 remain insoluble in an alkaline developer because the protecting group of the base polymer is not eliminated due to lack of generation of acid from the acid generator.

As shown in FIG. 8A, the resist film 41 is developed by being subjected to an alkaline developer 44 made of a 2.38 wt % tetramethylammonium hydroxide solution, for example, for 60 seconds.

As shown in FIG. 8B, the developed resist film 41 is rinsed with a rinsing liquid 47 of pure water sprayed in an atomized state from a spray head 46 for 60 seconds, to thereby form a resist pattern 45 composed of the non-exposed portions 41b of the resist film 41 having a line width of 0.11 μm, as shown in FIG. 8C.

In Embodiment 4, the developed resist film 41 is rinsed with the rinsing liquid 47 sprayed in an atomized state. Therefore, the rinsing liquid 47 less easily stay in openings of the resist pattern 45 compared with the case of supplying the rinsing liquid from a nozzle. This reduces the surface tension acting on the resist pattern 45, and thus the resist pattern 45 can be kept in a good shape without tilting/falling of pattern portions.

During the spraying of the atomized rinsing liquid 47 on the resist film 41, the resist film 41 is preferably rotated. By the rotation, the rinsing liquid 47 temporarily staying in the openings of the resist pattern 45 is moved outward swiftly, and therefore the surface tension acting on the resist pattern 45 greatly decreases.

In Embodiment 4, pure water was used as the rinsing liquid 47. Alternatively, the rinsing liquid 47 may be the alkaline rinsing liquid shown in Embodiment 1, or the organic solvent-containing rinsing liquid or the organic solvent-containing alkaline rinsing liquid shown in Embodiment 2.

While the present invention has been described in a preferred embodiment, it will be apparent to those skilled in the art that the disclosed invention may be modified in numerous ways and may assume many embodiments other than that specifically set out and described above. Accordingly, it is intended by the appended claims to cover all modifications of the invention which fall within the true spirit and scope of the invention.

What is claimed is:

1. A pattern formation method comprising the steps of:
forming a resist film made of a chemically amplified resist on a substrate;
exposing the resist film to light selectively to perform pattern exposure;
subjecting the pattern-exposed resist film to a developer; and
rinsing the resist film subjected to the developer to form a resist pattern made of the resist film,
wherein the step of rinsing is performed using an alkaline rinsing liquid.

2. The method of claim 1, wherein the alkaline rinsing liquid is a diluted alkaline developer.

3. A pattern formation method comprising the steps of:
forming a resist film made of a chemically amplified resist on a substrate;
exposing the resist film to light selectively to perform pattern exposure;
subjecting the pattern-exposed resist film to a developer; and
rinsing the resist film subjected to the developer to form a resist pattern made of the resist film,
wherein the step of rinsing is performed using a rinsing liquid containing an organic solvent.

4. The method of claim 3, wherein the organic solvent is selected from the group consisting of acetone, methanol, ethanol, isopropyl alcohol, ethyl lactate, propylene glycol methyl ether acetate, propylene glycol methyl ether and diglyme.

5. A pattern formation method comprising the steps of:
forming a resist film made of a chemically amplified resist on a substrate;
exposing the resist film to light selectively to perform pattern exposure;
subjecting the pattern-exposed resist film to a developer; and
rinsing the resist film subjected to the developer to form a resist pattern made of the resist film,
wherein the step of rinsing is performed using an alkaline rinsing liquid containing an organic solvent.

6. The method of claim 5, wherein the alkaline rinsing liquid is a diluted alkaline developer.

7. The method of claim 5, wherein the organic solvent is selected from the group consisting of acetone, methanol, ethanol, isopropyl alcohol, ethyl lactate, propylene glycol methyl ether acetate, propylene glycol methyl ether and diglyme.

8. A pattern formation method comprising the steps of:
forming a resist film made of a chemically amplified resist on a substrate;
exposing the resist film to light selectively to perform pattern exposure;
subjecting the pattern-exposed resist film to a developer; and
rinsing the resist film subjected to the developer to form a resist pattern made of the resist film,
wherein the step of rinsing comprises the step of supplying a rinsing liquid to the resist film while shaking the resist film.

9. The method of claim 8, wherein the rinsing liquid is an alkaline rinsing liquid or an alkaline rinsing liquid containing an organic solvent.

10. The method of claim 9, wherein the alkaline rinsing liquid is a diluted alkaline developer.

11. The method of claim 9, wherein the organic solvent is selected from the group consisting of acetone, methanol, ethanol, isopropyl alcohol, ethyl lactate, propylene glycol methyl ether acetate, propylene glycol methyl ether and diglyme.

12. A pattern formation method comprising the steps of:
forming a resist film made of a chemically amplified resist on a substrate;
exposing the resist film to light selectively to perform pattern exposure;
subjecting the pattern-exposed resist film to a developer; and
rinsing the resist film subjected to the developer to form a resist pattern made of the resist film,
wherein the step of rinsing comprises the step of spraying an atomized rinsing liquid on the resist film.

13. The method of claim 12, wherein the rinsing liquid is an alkaline rinsing liquid or an alkaline rinsing liquid containing an organic solvent.

14. The method of claim 13, wherein the alkaline rinsing liquid is a diluted alkaline developer.

15. The method of claim 13, wherein the organic solvent is selected from the group consisting of acetone, methanol, ethanol, isopropyl alcohol, ethyl lactate, propylene glycol methyl ether acetate, propylene glycol methyl ether and diglyme.
